(19) United States
(12) Patent Application Publication
(10) Pub. No.: US 2026/0251718 A1
(43) Pub. Date: Aug. 27, 2026

(54) METHOD, APPARATUS, AND MACHINE-READABLE PROGRAM PRODUCT FOR DETERMINING STATE OF CHARGE OF A BATTERY

(71) Applicant: O2Micro Inc., Santa Clara, CA (US)

(72) Inventors: Cheng HUANG, Wuhan (CN); Jing CHE, Wuhan (CN); Sterling DU, Palo Alto, CA (US); Heng YANG, Wuhan (CN)

(21) Appl. No.: 19/368,530

(22) Filed: Oct. 24, 2025

(30) Foreign Application Priority Data
Oct. 31, 2024 (CN) 202411546031.7

(51) Int. Cl. G01R 31/382; G01R 31/367

(52) U.S. Cl. CPC G01R 31/382; G01R 31/367

(57) ABSTRACT

A method for determining a state of charge (SOC) of a battery includes: calculating an SOC variation based on a variation in charge quantity and corrected full charge capacity (FCC) of the battery; and calculating a present SOC based on a previous SOC and the SOC variation. The corrected FCC is determined through correction of a value of an initial FCC using a modification parameter. The previous SOC is determined based on an SOC database that stores a battery parameter and an SOC associated with each other. The modification parameter is determined based on an FCC database that stores a battery parameter and an FCC modification parameter associated with each other. The FCC modification parameter is determined based on an error between SOC historical data (determined using a previous corrected FCC) and SOC regular data (determined using a method that calculates a charge quantity stored in the battery).

### RELATED APPLICATION

This application claims benefit under 35 U.S.C. § 119(a) to Application No. 202411546031.7, filed with the State Intellectual Property Office of the People's Republic of China on Oct. 31, 2024, which is hereby incorporated by reference in its entirety.

### FIELD

The present disclosure relates to the technical field of new energy, and in particular to a battery management technology. More specifically, the present disclosure relates to a method, apparatus, and machine-readable program product for determining a state of charge of a battery.

### BACKGROUND

With widespread use of battery-powered electronic devices such as mobile phones and palmtop computers, accurate presentation of a state of charge (SOC) of a battery is an important performance indicator for those and other products. SOC is for indicating a state of remaining charge level of a battery, and is for example represented by a ratio of the battery's remaining capacity to its charge capacity in a fully charged state (that is, its full charge capacity, FCC). Inaccurate determination of the SOC of the battery may result in poor user experience. This includes an erratically varying SOC display, the device shutting down unexpectedly even though the SOC shows remaining power, or continued charging after the battery is full. More specifically, the device may shutdown when the battery is fully discharged, but the SOC indicates power remains. Conversely, the battery may be fully charged while the SOC shows it is not. These inaccuracies can accelerate battery aging and potentially damage the battery. In conventional technology, methods for estimating a state of charge of a battery include a discharge testing method, a Coulomb integration method, an open-circuit voltage method, a method combining the Coulomb integration method with the open-circuit voltage method, a dynamic voltage method, and the like.

In the discharge testing method, discharging is performed at a constant current and a certain discharge rate to obtain a measure of the electricity discharged by a battery and thereby estimate an SOC value. The method is generally applied as a reference standard for battery capacity testing, but requires a strict testing condition and is only suitable for data collection in a laboratory environment.

In the Coulomb integration method, an SOC of a battery is dynamically estimated by accumulating variations in electric capacity during charging and discharging. The method is simple in calculation, easy for implementation, and has a low requirement for a microprocessor. However, the Coulomb integration method requires prior knowledge of an initial SOC of the battery and is prone to an accumulative error. As an operating condition of a lithium battery varies, a total available discharge capacity of the battery varies. Especially at a low temperature (below 0° C.), the total available discharge capacity of the lithium battery decreases significantly. Due to the accumulative error caused by Coulomb integration and the variable total available discharge capacity, it is difficult to accurately estimate a remaining capacity.

In the open-circuit voltage (OCV) method, an SOC is inferred indirectly by measuring a relationship between an open-circuit voltage of a battery and a concentration of lithium ions inside the battery. The target battery is required to be inactive, e.g., neither charging nor discharging, for over one hour. At different temperatures or stages of battery lifetime, the SOC inferred according to the open-circuit voltage method may differ significantly from an actual (on-ground) SOC.

In the method combining the Coulomb integration with the open-circuit voltage, the accumulative error in the Coulomb integration is eliminated, but the problem of variation in a total available discharge capacity of the battery due to variation in an operating condition, such as changes in ambient temperature, is still not addressed.

The dynamic voltage method is simple in structure and requires low computing capacity of a microprocessor. Due to an acquisition error for a battery voltage and a nonlinear relationship between a voltage and an SOC, accuracy of the method is low. As a result, the dynamic voltage method is applicable only to low-cost mobile devices having a low requirement for accuracy.

Therefore, it would be useful to have a method for quickly determining a state of charge of a battery, where the method has low power consumption, small storage space, low sensitivity to temperature and other battery-related parameters, broader applicability, and improved accuracy.

### SUMMARY

Hereinafter provided is a brief summary of the present disclosure, which is intended to provide a basic understanding of aspects of the present disclosure. This summary is not an exhaustive overview of the present disclosure. The summary is not intended to identify key or critical portions of the present disclosure or to limit the scope of the present disclosure. The purpose is merely to present concepts in a simplified form, which serves as a preamble of a more detailed description to be discussed later.

According to an aspect of the present disclosure, a method for determining a state of charge (SOC) of a battery is provided. The method includes: calculating an SOC variation of the battery based on a variation in charge quantity stored in the battery and a corrected full charge capacity (FCC); and calculating a present SOC based on a previous SOC and the SOC variation. The corrected FCC is determined through correction of a value of an initial FCC using an FCC modification parameter. The previous SOC is determined at least partially based on an SOC database that stores a battery parameter and an SOC that are associated with each other. The FCC modification parameter is determined based on an FCC database that stores at least a battery parameter and an FCC modification parameter that are associated with each other. The FCC modification parameter stored in the FCC database is determined based on an error between SOC historical data and SOC regular data. The SOC historical data is determined using a previous corrected FCC, and the SOC regular data is determined using a method that calculates a charge quantity stored in the battery. The method has low power consumption, small storage space, low sensitivity to temperature and other battery-related parameters, broader applicability, and improved accuracy.

### BRIEF DESCRIPTION OF THE DRAWINGS

For further illustration of the above and other advantages and features of the present disclosure, embodiments of the present disclosure are described in detail hereinafter in conjunction with accompanying drawings. The drawings, together with the detailed description below, are included in and form a part of the specification. Elements having the same function and structure are denoted by the same reference numerals. The drawings illustrate examples of the present disclosure and should not be construed as a limitation to the scope of the present disclosure. In the accompanying drawings:

FIG. 1 illustrates a flowchart of a method for determining a state of charge of a battery according to an embodiment of the present invention;

FIG. 2 illustrates a flowchart of a method for determining a state of charge of a battery according to an embodiment of the present invention;

FIG. 3A illustrates a flowchart of an FCC initial correction step according to an embodiment of the present invention;

FIG. 3B illustrates a flowchart of querying an FCC database in a manner of two-dimensional linear interpolation according to an embodiment of the present invention;

FIG. 4 illustrates a flowchart of an FCC real-time correction step according to an embodiment of the present invention;

FIG. 5A illustrates a flowchart of a method for determining a state of charge of a battery according to an embodiment of the present invention;

FIG. 5B shows a diagram of selection of a record point in recording discharge state data according to an embodiment of the present invention;

FIG. 6 of the present invention illustrates a flowchart of dynamically updating a first FCC database according to an embodiment;

FIG. 7 illustrates a flowchart of dynamically updating a second FCC database according to an embodiment of the present invention;

FIG. 8 illustrates an apparatus for determining a state of charge of a battery according to an embodiment of the present invention;

FIG. 9A shows a discharge SOC curve and an SOC error curve after 1 to 11 rounds of adaptive compensation correction according to an embodiment of the present invention;

FIG. 9B shows a discharge SOC curve and an SOC error curve after 12 to 22 rounds of adaptive compensation correction according to an embodiment of the present invention; and

FIG. 9C shows a distribution of a discharge SOC error after 1 to 22 rounds of adaptive compensation correction according to an embodiment of the present invention.

Embodiments of the present disclosure are described below in conjunction with the drawings. For the sake of clarity and conciseness, not all features of an actual embodiment are described in the specification. However, numerous embodiment-specific decisions, for example, in accord with constraining conditions related to system and business, should or may be made when developing any of such actual embodiments, so as to achieve specific targets of a developer. These constraining conditions may vary with different embodiments. Furthermore, for those skilled in the art who benefit from the present disclosure, such development work is only a routine task.

Herein, in order to avoid obscuring the present disclosure due to unnecessary details, only apparatus structures and/or processing steps closely related to the solutions according to the present disclosure are illustrated in the drawings, and other details less related to the present disclosure are omitted.

Reference will now be made in detail to the various embodiments of the present disclosure, examples of which are illustrated in the accompanying drawings. While described in conjunction with these embodiments, they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

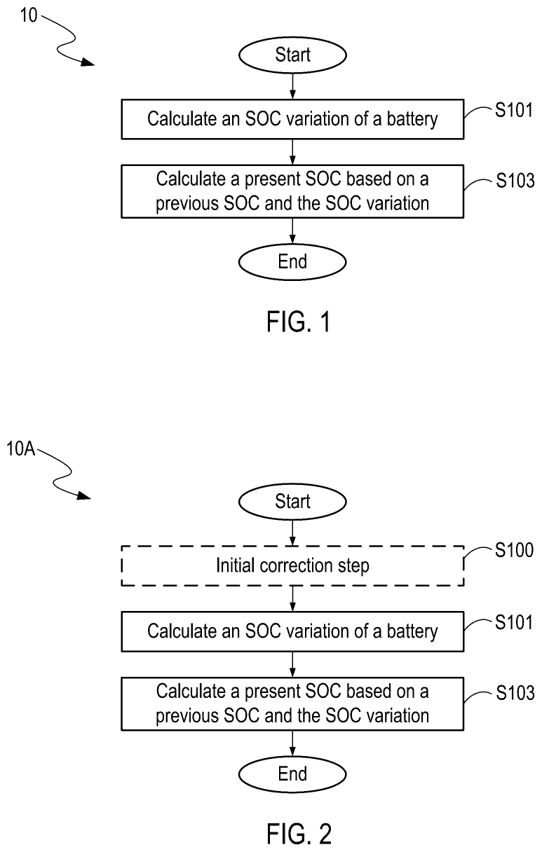

It should be borne in mind, however, that all of these and similar terms are to be associated with the appropriate physical quantities and are merely convenient labels applied to these quantities. Unless specifically stated otherwise as apparent from the following discussions, throughout the present disclosure, discussions utilizing terms such as “calculating,” “obtaining,” “querying,” “correcting,” “storing,” “determining,” “updating,” “measuring,” or the like, may refer to actions and processes of and executed by an apparatus or computer system or similar electronic computing device or processor (e.g., the actions and processes of the methods of FIGS. 1, 2, 3A, 3B, 4, 5A, 6, and 7). A computer system or similar electronic computing device manipulates and transforms data represented as physical (electronic) quantities within memories, registers or other such information storage, transmission or display devices. In its most basic configuration, a computer system or the like includes at least one processing unit and memory. The computer system may also have additional features and/or functionality, such as the capability for communicating with other devices, the capability to receive user inputs, and the capability to display results.

Embodiments described herein may be discussed in the general context of computer-executable instructions residing on some form of computer-readable storage medium, such as modules, executed by one or more computers, other devices, or circuits. By way of example, and not limitation, computer-readable storage media may comprise non-transitory computer storage media and communication media. Generally, modules may include software, routines, programs, objects, components, data structures, etc., that perform particular tasks or implement particular abstract data types. The functionality of the modules may be combined or distributed as desired in various embodiments. Modules may also be implemented using circuits such as an acquisition circuit or a processing circuit (e.g., a chip or a processor). Moreover, the modules are merely logical modules defined based on specific functions implemented by the modules and are not intended to limit an implementation. For example, a module may be implemented by one or more application-specific integrated circuits, software programs, or a combination thereof.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory (e.g., an SSD) or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media may embody computer-executable instructions, data structures, and modules, and includes any information delivery media. By way of example, and not limitation, communication media may include wired media such as a wired network or direct-wired connection, and wireless media such as acoustic, radio frequency (RF), infrared and other wireless media. Combinations of any of the above can also be included within the scope of computer-readable media.

As used herein, the term “parameter” or the like may be the name of a property or metric (e.g., “temperature”) or the numerical value of that property or metric (e.g., 90° C.). A person of ordinary skill in the art will understand how the term is being used.

### Method, Apparatus, and Machine-Readable Program Product for Determining State of Charge of a Battery

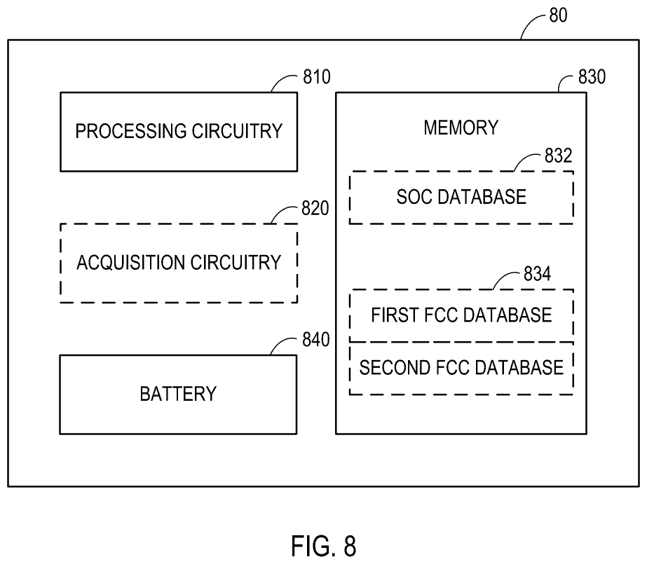

As discussed in the background above, accurate presentation of a state of charge (SOC) of a battery is an important performance indicator in battery-powered electronic devices such as but not limited to mobile phones and palmtop computers. Embodiments according to the presently disclosed invention are integrated into a practical application, namely the accurate and efficient calculation of SOC in real time. More specifically, these embodiments improve the accuracy of the SOC estimation. This improvement provides a dual benefit: it improves device performance by preventing unexpected shutdowns, and it extends battery lifespan by mitigating conditions that accelerate aging, such as deep discharge and overcharging. The ranges of values of the parameters used to calculate SOC, and the various combinations of those parameters and their values, can complicate the calculation of SOC; therefore, accurate, quick, and efficient calculations of SOC is beyond the capability of a human and relies on the use of a computing system or the like (e.g., FIG. 8), particularly considering the time constraints associated with determining SOC in real time.

### First Embodiment

A method for determining a state of charge of a battery is provided according to a first embodiment of the present invention. The method has low power consumption, small storage space, low sensitivity to temperature and other battery-related parameters, broader applicability, and improved accuracy. These factors (particularly low power consumption, small storage space, and low sensitivity to temperature and other battery-related parameters) are important considerations in battery-powered electronic devices, and thus the method can improve the performance of such devices relative to the conventional methods described above.

FIG. 1 illustrates a flowchart of a method for determining a state of charge of a battery according to the first embodiment. As shown in FIG. 1, a method 10 includes step S101 and step S103. In step S101, a state of charge (SOC) variation of the battery is calculated based on a variation in charge quantity stored in the battery and a corrected full charge capacity (FCC) determined through correction by an FCC modification parameter. In step S103, a present SOC is calculated based on a previous SOC and the SOC variation of the battery. Here, the previous SOC is determined at least partially based on an SOC database that stores a battery parameter and an SOC in association with each other. In other words, the SOC database includes values of SOC as a function of (indexed by) respective values of the battery parameter. Furthermore, the FCC modification parameter is determined using an FCC database that stores at least a battery parameter and an FCC modification parameter in association with each other (e.g., the FCC modification parameter is a function of or indexed by the battery parameter), and the FCC modification parameter stored in the FCC database is determined based on an error between SOC historical data and what may be referred to herein as “SOC regular data.” The SOC historical data can be determined using a corrected FCC, and the SOC regular data is determined using a regular SOC estimation method not involving the corrected FCC. The regular SOC estimation method can include a method that is closely related to an actual status or a real-time status of the charges stored in the battery. For example, the regular SOC estimation method can include the Coulomb integration method, e.g., calculating a charge quantity stored in the battery. Thus, in some embodiments, the SOC regular data can be referred to as “SOC actual data.”

In step S101, the variation in charge quantity stored in the battery may be determined, for example, through measurement. In an embodiment, the variation in charge quantity is expressed by an integral difference ΔCCₙ between a present instance n (where n is a natural number) and a previous instance n−1, which is measured using a coulombmeter. For example, a ratio of the variation in charge quantity ΔCCₙ to the corrected FCC may be calculated and determined as the present SOC variation ΔSOCₙ:

$${Δ SOC}_{n} = {Δ CC}_{n} / {FCC}_{corrected} . \qquad Equation ( l )$$

In step S103, for example, a present SOCₙ may be calculated based on SOCₙ₋₁ at a previous instant, that is instant (n−1), of the battery and the present SOC variation ΔSOCₙ through the following equation:

$${SOC}_{n} = {SOC}_{n - 1} + {Δ SOC}_{n} . \qquad Equation ( 2 )$$

The corrected FCC in step S101 is obtained (e.g., read) from the FCC database, and the previous SOC in step S103 is determined at least partially based on the SOC database. In an embodiment, the SOC database stores SOC values obtained (measured) by discharging the battery with different battery parameters.

As an example, in an initial discharge stage, an initial SOC₀ may be determined by querying the SOC database, and then other SOCs at different points in time may be calculated in an recursive manner. In other words, although not shown in the figure, step S101 and step S103 of the method 10 may be performed repeatedly and recursively until a termination condition is met, such as completion of a discharge cycle.

To use the above-described FCC database and SOC database, a process of determining a required battery parameter (a present battery parameter and/or a battery parameter in the initial discharge stage) is performed before or between step S101 and step S103. Such a process is described in conjunction with, and can be executed using, the apparatus 80 of FIG. 8. A battery parameter may include, but is not limited to, a battery voltage (voltage across terminals of the battery), a battery current (current flowing through the battery), and/or a battery temperature, among others. In an embodiment, the types of battery parameters in the FCC database at least partially correspond to or overlap the types of battery parameters in the SOC database.

In this way, the SOC may be calculated by using a corrected FCC determined by correcting an error between SOC historical data and SOC regular data, so that the accuracy of determining the SOC is improved.

Next, details of the FCC database and the SOC database, and processes using these databases, are further described below.

In an embodiment of the method 10 for determining a state of charge of a battery, the FCC database may include: a first FCC database storing a first battery parameter in an initial discharge stage and an initial FCC modification value (as a first FCC modification parameter) in association with each other; and/or a second FCC database storing a second battery parameter and a real-time FCC modification coefficient (as a second FCC modification parameter) in association with each other.

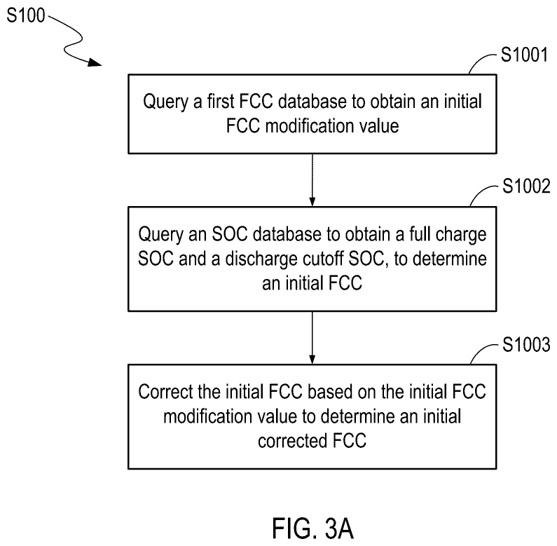

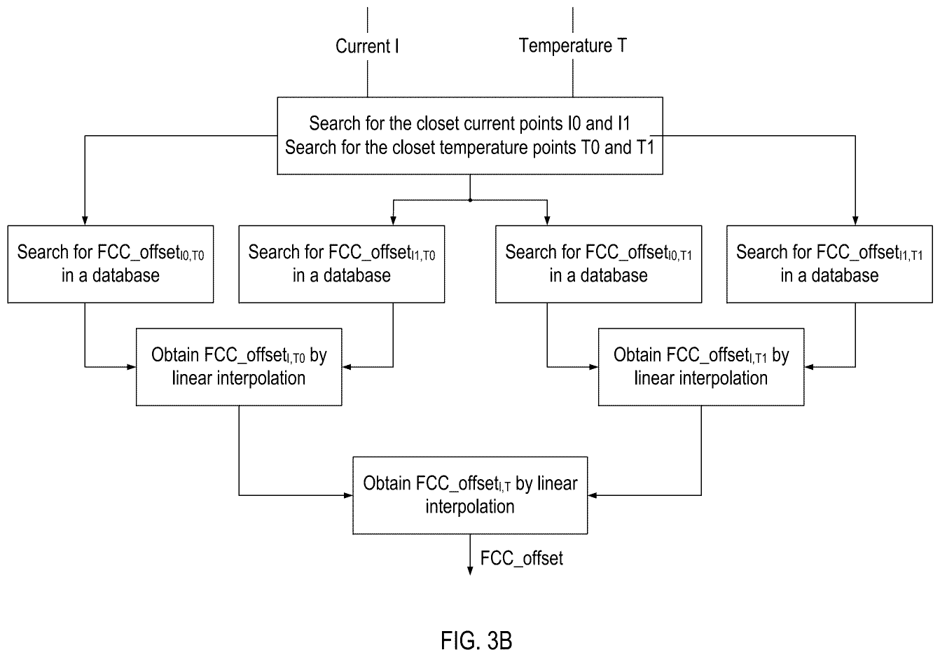

First, with reference to FIG. 2 and FIG. 3A, an embodiment of the FCC database including a first FCC database for initial correction is described. In an embodiment, the first battery parameter in the first FCC database includes battery current and temperature. In that embodiment, as shown in FIG. 2, a method 10A includes an initial correction step S100, details of which are shown in FIG. 3A. That is, the initial correction step S100 may include step S1001 to step S1003. In step S1001, the first FCC database is queried based on the battery parameter in the initial discharge stage to obtain an initial FCC modification value. In step S1002, the SOC database is queried based on the battery parameter in the initial discharge stage to obtain a full charge SOC and a discharge cutoff SOC, to determine an initial FCC. In step S1003, the initial FCC is corrected based on the initial FCC modification value to determine an initial corrected FCC. The initial FCC is determined as described further below.

As an example, the first FCC database may describe FCC modification values under conditions of (as a function of) specific temperatures T and specific currents I. The first FCC database includes two data space dimensions, e.g., temperature and current. A data value within a data space represents an FCC modification value during a discharge process under a condition corresponding to the data space.

As an example, in step S1001, an initial FCC modification value FCC_offset is obtained by querying the first FCC database based on the battery current and temperature (I, T) in the initial discharge stage.

The query of the first FCC database (step S1001) is implemented with a two-dimensional linear interpolation algorithm, as shown in FIG. 3B. An example execution flow of the two-dimensional linear interpolation algorithm may include steps a1, a2, and a3 described as follows.

In step a1, current points I₀ and I₁ closest to the current I and temperature points T₀ and T₁ closest to the temperature T are searched for in the first FCC database based on the battery parameter (I, T) in the initial discharge stage.

Step a2 includes the following steps.
(1) An FCC modification value FCC_offset_{I0,T0} corresponding to the current I₀ and the temperature point T₀, and an FCC modification value FCC_offset_{I1,T0} corresponding to the current I₁ and the temperature point T₀, are searched for in the first FCC database, and a first-order linear interpolation is then performed to calculate FCC_offset_{I,T0}:

$${FCC\_offset}_{I , T 0} = \frac{{FCC\_offset}_{I 1 , T 0} - {FCC\_offset}_{I 0 , T 0}}{{I}_{1} - {I}_{0}} * ( I - {I}_{0} ) + {FCC\_offset}_{I 0 , T 0} .$$

(2) An FCC modification value FCC_offset_{I0,T1} corresponding to the current I₀ and the temperature point T₁, and an FCC modification value FCC_offset_{I1,T1} corresponding to the current I₁ and the temperature point T₁, are searched for in the first FCC database, and a first-order linear interpolation is then performed to calculate FCC_offset_{I,T1}:

$${FCC\_offset}_{I , T 1} = \frac{{FCC\_offset}_{I 1 , T 1} - {FCC\_offset}_{I 0 , T 1}}{{I}_{1} - {I}_{0}} * ( I - {I}_{0} ) + {FCC\_offset}_{I 0 , T 1} .$$

In step a3, a first-order linear interpolation is performed using the FCC_offset_{I,T0} and FCC_offset_{I,T1} calculated in step a2 to calculate an initial FCC modification value FCC_offset under a condition of battery parameter (I, T) in the initial discharge stage:

$$FCC\_offset = \frac{{FCC\_offset}_{I , T 1} - {FCC\_offset}_{I , T 0}}{{T}_{1} - {T}_{0}} * ( T - {T}_{0} ) + {FCC\_offset}_{I , T 0} .$$

Next, in step S1002, the SOC database is queried based on the battery parameter in the initial discharge stage, and/or other parameters (including but not limited to charge/discharge cutoff voltage, charge cutoff current, discharge load current, and battery temperature T), to determine a full charge SOC and a discharge cutoff SOC, which are used to determine an initial FCC. in an embodiment, the battery parameter in the SOC database includes a battery voltage, a battery current, and a battery temperature.

As an example, a specific process for determining an initial FCC (step S1002) may include steps b1, b2, and b3 described as follows.

In step b1, the SOC database is searched based on the charge cutoff voltage, the charge cutoff current, charge battery temperature, to obtain SOC_{full} of the battery when the battery is fully charged. In an embodiment, the battery temperature is sampled in real-time throughout the charge process. In step b1, charge battery temperature used for searching the SOC database is obtained by calculating a present single sampled value of the battery temperature. Note that the “present single sampled value” of the battery temperature and calculation of the “charge battery temperature” based on the present single sampled value are not restricted in the present disclosure. By way of example only, the “present single sampled value” of the battery temperature can be a sampled value taken at a charge cutoff instant, and the sampled value can be simply treated as the “charge battery temperature.” Similarly, in an alternative example, a sampled value of the battery temperature may be selected from other sampled values of the battery temperature during the charge process or from statistics of these sampled values based on practical situations, which is not described in further detail here.

In step b2, the SOC database is queried based on the discharge cutoff voltage, the discharge load current, and the discharge battery temperature, to obtain the cutoff SOC_{end} of the battery when the discharge ends. In an embodiment, the battery temperature is sampled in real-time throughout the discharge process. In step b2, the discharge battery temperature used for searching the SOC database is determined by calculating a present single sampled value of the battery temperature. Note that the “present single sampled value” of the battery temperature and calculation of the “discharge battery temperature” based on the present single sampled value are not restricted in the present disclosure. By way of example only, the “present single sampled value” of the battery temperature can be a sampled value taken at a discharge cutoff instant, and the sampled value can be simply treated as the “discharge battery temperature.” Similarly, in an alternative example, a sampled value of the battery temperature may be selected from other sampled values of the battery temperature during the discharge process or from statistics of these sampled values based on practical situations, which is not described in further detail here.

In step b3, based on a design capacity FCC_{design} of the battery, an actual remaining capacity RCA_{dsg} after a discharge task is determined as the initial FCC.

$${RCA}_{dsg} = {FCC}_{design} * ( {SOC}_{full} - {SOC}_{end} ) .$$

Then, in step S1003, the initial FCC (RCA_{dsg}) is corrected based on the initial FCC modification value FCC_offset using the following equation, to determine an initial corrected FFC₀:

$${FCC}_{0} = {RCA}_{dsg} + FCC\_offset . \qquad Equation ( 3 )$$

In an embodiment, in a case where step S101 to step S103 (FIG. 2) are performed recursively, the FCC₀ is applied as the FCC_{corrcted} in Equation (1) in the process of step S101 in each subsequent recursive step, to calculate a present SOC variation ΔSOCₙ.

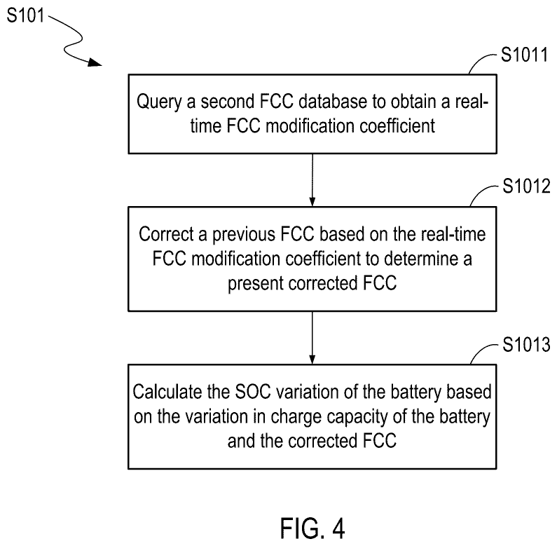

Next, with reference to FIG. 4, an embodiment of a method of correcting FCC in a database that includes the second FCC database for real-time correction is described. In one such embodiment, the second battery parameter in the second FCC database includes a battery current, a battery voltage, and an SOC. In this embodiment, as shown in FIG. 4, step S101 of FIG. 2 includes step S1011 to step S1013. In step S1011, the second FCC database is queried based on the present battery parameter to obtain a real-time FCC modification coefficient. In step S1012, a previous FCC is corrected based on the real-time FCC modification coefficient to determine a present corrected FCC. In step S1013, the SOC variation of the battery is calculated based on the variation in charge quantity of the battery and the corrected FCC. Because the FCC varies dynamically with a present state of charge, temperature, and current during the discharge process, a SOC calculation result determined with the present corrected FCC that was determined through real-time correction based on the second FCC database is more precise.

As an example, in step S1011, a second FCC database is queried based on a battery parameter at a present instant n (battery current, battery temperature, and a previously determined SOC (that is, SOCₙ₋₁ at a previous instant n−1)) to determine a real-time FCC modification coefficient FCCᵣₐₜᵢₒ₋ₙ.

In step S1012, based on the previous FCC, such as FCCₙ₋₁ at the previous instant n−1, and the real-time FCC modification coefficient FCCᵣₐₜᵢₒ₋ₙ, a present corrected FCCₙ is calculated with the following equation:

$${FCC}_{n} = {FCC}_{n - 1} * {FCC}_{ratio - n} . \qquad Equation ( 4 )$$

Next, in step S1013, FCCₙ is applied as the corrected FCC (that is, FCC_{corrcted}), and based on a variation in charge quantity CC_{delta-n} of the battery at the present instant, an SOC variation of the battery is calculated, through the above-described equation (1), as

$$Δ {SOC}_{n} = {CC}_{delta - n} / {FCC}_{n} .$$

Next, a modified example of the above example of real-time correction is discussed. The difference between this example and the prior one is that in step S1012, an SOC correction factor SOC_{factor-n} at the present instant n, which may be also referred to as a remaining capacity error factor, is included in the calculation of FCCₙ. Specifically, the present corrected FCCₙ is calculated using the following variant of Equation (4):

$${FCC}_{n} = {FCC}_{n - 1} * {FCC}_{ratio - n} * {SOC}_{factor - n} . \qquad Equation ( {4}^{′} )$$

The correction factor SOC_{factor-n} is obtained before step S1012. For example, the correction factor SOC_{factor-n} may be obtained in step S1011, before step S1011, or between steps S1011 and S1012. An example process of obtaining the correction factor SOC_{factor-n} may includes steps c1 and c2 described as follows.

In step c1, the SOC database is queried to obtain an SOC estimated value SOCₑₛₜ.

The SOC database is searched based on present battery voltage, present battery current, and battery temperature to obtain the SOC estimated value SOCₑₛₜ. The SOC database is searched based on the discharge cutoff voltage, the discharge load current, and the battery temperature to obtain a battery cutoff SOC_{end} when the discharge ends. Then, (SOCₑₛₜ−SOC_{end}), representing a remaining charge level, is calculated.

In step c2, the SOC correction factor at the present instant n is calculated based on a previously obtained SOC (SOCₙ₋₁):

$${SOC}_{factor - n} = ( {SOC}_{est} - {SOC}_{end} ) / ( {SOC}_{n - 1} - {SOC}_{end} ) .$$

Next, an example process of obtaining the FCCᵣₐₜᵢₒ₋ₙ in step S1011 is described.

As an example, the second FCC database may describe an FCC modification coefficient under a condition of a specific state of charge SOC, a specific temperature T, and a specific current I. The second FCC database includes three data space dimensions: state of charge, temperature, and current. A data value within a data space represents an FCC modification coefficient during a discharge process under a situation corresponding to the data space.

As an example, the real-time FCC modification coefficient is obtained by querying the second FCC database, and the query of the second FCC database can be implemented with a three-dimensional linear interpolation algorithm. An example execution flow of the three-dimensional linear interpolation algorithm may include steps d1, d2, d3, and d4 described as follows.

In step d1, for example, a battery parameter to be queried in the FCC database is indexed by (SOC, I, T). Specifically, the states of charge SOC₀ and SOC₁ (which may be also referred to as discharge depth or applied as an indicator of the discharge depth) closest to the SOC, the current points I₀ and I₁ closest to the current I, and the temperature points T₀ and T₁ closest to the temperature T of the battery, are searched for in the second FCC database.

Step d2 includes the following steps.
(1) FCC_ratio_{SOC0,I0,T0} corresponding to the state of charge SOC₀, the current I₀, and the temperature point T₀, and FCC_ratio_{SOC1,I0,T0} corresponding to the state of charge SOC₁, the current I₀ and the temperature point T₀, are searched for in the second FCC database, respectively, and a first-order linear interpolation is performed to determine FCC_ratio_{SOC,I0,T0}:

$${FCC\_ratio}_{SOC , I 0 , T 0} = \frac{{FCC\_ratio}_{SOC 1 , I 0 , T 0} - {FCC\_ratio}_{SOC 0 , I 0 , T 0}}{{SOC}_{1} - {SOC}_{0}} * ( SOC - {SOC}_{0} ) + {FCC\_ratio}_{SOC 0 , I 0 , T 0} .$$

(2) FCC_ratio_{SOC0,I1,T0} corresponding to the state of charge SOC₀, the current I₁, and the temperature point T₀, and FCC_ratio_{SOC1,I1,T0} corresponding to the state of charge SOC₁, the current I₁ and the temperature point T₀, are searched for in the second FCC database, respectively, and a first-order linear interpolation is performed to determine FCC_ratio_{SOC,I1,T0}:

$${FCC\_ratio}_{SOC , I 1 , T 0} = \frac{{FCC\_ratio}_{SOC 1 , I 1 , T 0} - {FCC\_ratio}_{SOC 0 , I 1 , T 0}}{{SOC}_{1} - {SOC}_{0}} * ( SOC - {SOC}_{0} ) + {FCC\_ratio}_{SOC 0 , I 1 , T 0} .$$

(3) FCC_ratio_{SOC0,I0,T1} corresponding to the state of charge SOC₀, the current I₀, and the temperature point T₁, and FCC_ratio_{SOC1,I0,T1} corresponding to the state of charge SOC₁, the current I₀ and the temperature point T₁, are searched for in the second FCC database, respectively, and a first-order linear interpolation is performed to determine FCC_ratio_{SOC,I0,T1}:

$${FCC\_ratio}_{SOC , I 0 , T 1} = \frac{{FCC\_ratio}_{SOC 1 , I 0 , T 1} - {FCC\_ratio}_{SOC 0 , I 0 , T 1}}{{SOC}_{1} - {SOC}_{0}} * ( SOC - {SOC}_{0} ) + {FCC\_ratio}_{SOC 0 , I 0 , T 1} .$$

(4) FCC_ratio_{SOC0,I1,T1} corresponding to the state of charge SOC₀, the current I₁, and the temperature point T₁, and FCC_ratio_{SOC1,I1,T1} corresponding to the state of charge SOC₁, the current I₁ and the temperature point T₁, are searched for in the second FCC database. respectively, and a first-order linear interpolation is performed to determine FCC_ratio_{SOC,I1,T1}:

$${FCC\_ratio}_{SOC , I 1 , T 1} = \frac{{FCC\_ratio}_{SOC 1 , I 1 , T 1} - {FCC\_ratio}_{SOC 0 , I 1 , T 1}}{{SOC}_{1} - {SOC}_{0}} * ( SOC - {SOC}_{0} ) + {FCC\_ratio}_{SOC 0 , I 1 , T 1} .$$

Step d3 includes the following steps.
(1) A first-order linear interpolation is performed using FCC_ratio_{SOC,I0,T0} and FCC_ratio_{SOC,I1,T0} calculated in step d2 to determine

$${FCC\_ratio}_{SOC , I , T 0} = \frac{{FCC\_ratio}_{SOC , I 1 , T 0} - {FCC\_ratio}_{SOC , I 0 , T 0}}{{I}_{1} - {I}_{0}} * ( I - {I}_{0} ) + {FCC\_ratio}_{SOC , I 0 , T 0}$$

(2) A first-order linear interpolation is performed using FCC_ratio_{SOC,I0,T1} and FCC_ratio_{SOC,I1,T1} calculated in step d2 to obtain determine:

$${FCC\_ratio}_{SOC , I , T 1} = \frac{{FCC\_ratio}_{SOC , I 1 , T 1} - {FCC\_ratio}_{SOC , I 0 , T 1}}{{I}_{1} - {I}_{0}} * ( I - {I}_{0} ) + {FCC\_ratio}_{SOC , I 0 , T 1} .$$

In step d4, a first-order linear interpolation is performed using FCC_ratio_{SOC,I,T0} and FCC_ratio_{SOC,I,T1} calculated in step d3 to determine:

$${FCC\_ratio}_{SOC , I , T} = \frac{{FCC\_ratio}_{SOC , I , T 1} - {FCC\_ratio}_{SOC , I , T 0}}{{T}_{1} - {T}_{0}} * ( T - {T}_{0} ) + {FCC\_ratio}_{SOC , I , T 0} .$$

The value of FCC_ratio_{SOC,I,T} determined in this manner is applied as FCCᵣₐₜᵢₒ₋ₙ determined in step S1011 for the battery parameter set (SOC, I, T).

The initial FCC offset and the real-time FCC offset are described above with reference to FIG. 2 to FIG. 4. Note that although different examples are described separately, those examples may be combined with each other; that is, both the initial FCC offset and the real-time FCC offset may be applied simultaneously to achieve effects and benefits of using both.

Next, further details of obtaining a required SOC (e.g., the previous SOC mentioned in relation to step S103 in FIG. 1, the full charge SOC and discharge cutoff SOC mentioned in relation to step 1002 in FIG. 3A) from the SOC database based on the battery parameter are provided.

As an example, the battery parameter in the SOC database includes a battery voltage, a battery current, and a battery temperature. That is, the SOC database may describe a corresponding SOC state of the battery under a condition of a specific temperature T, a specific current I, and specific voltage V. In this example, the SOC database includes three data space dimensions, i.e., temperature, current, and voltage. A data value within a data space represents an SOC value of the battery under a situation corresponding to the data space.

The query of the SOC database may be implemented through a three-dimensional linear interpolation algorithm. An example execution flow of the three-dimensional linear interpolation algorithm include steps e1, e2, e3, and e4 described as follows.

In step e1, for example, a battery parameter to be queried is (V, I, T), voltage points V₀ and V₁ closest to terminal voltage V, current points I₀ and I₁ closest to the current I, and temperature points T₀ and T₁ closest to the temperature T are searched for in the SOC database.

Step e2 includes the following steps.
(1) SOC_{V0,I0,T0} corresponding to the terminal voltage V₀, the current I₀, and the temperature point T₀, and SOC_{V1,I0,T0} corresponding to the terminal voltage V₁, the current I₀, and the temperature point T₀, are respectively searched for in the SOC database, and a first-order linear interpolation is performed to obtain SOC_{V,I0,T0}, as follows:

$${SOC}_{V , I 0 , T 0} = \frac{{SOC}_{V 1 , I 0 , T 0} - {SOC}_{V 0 , I 0 , T 0}}{{V}_{1} - {V}_{0}} * ( V - {V}_{0} ) + {SOC}_{V 0 , I 0 , T 0} .$$

(2) SOC_{V0,I1,T0} corresponding to the terminal voltage V₀, the current I₁, and the temperature point T₀, and SOC_{V1,I1,T0} corresponding to the terminal voltage V₁, the current I₁, and the temperature point T₀, are respectively searched for in the SOC database, and a first-order linear interpolation is performed to obtain SOC_{V,I1,T0}, as follows:

$${SOC}_{V , I 1 , T 0} = \frac{{SOC}_{V 1 , I 1 , T 0} - {SOC}_{V 0 , I 1 , T 0}}{{V}_{1} - {V}_{0}} * ( V - {V}_{0} ) + {SOC}_{V 0 , I 1 , T 0} .$$

(3) SOC_{V0,I0,T1} corresponding to the terminal voltage V₀, the current I₀, and the temperature point T₁, and SOC_{V1,I0,T1} corresponding to the terminal voltage V₁, the current I₀, and the temperature point T₁, are respectively searched for in the SOC database, and a first-order linear interpolation is performed to obtain SOC_{V,I0,T1} as follows:

$${SOC}_{V , I 0 , T 1} = \frac{{SOC}_{V 1 , I 0 , T 1} - {SOC}_{V 0 , I 0 , T 1}}{{V}_{1} - {V}_{0}} * ( V - {V}_{0} ) + {SOC}_{V 0 , I 0 , T 1} .$$

(4) SOC_{V0,I1,T1} corresponding to the terminal voltage V₀, the current I₁, and the temperature point T₁ and SOC_{V1,I1,T1} corresponding to the terminal voltage V₁, the current I₁, and the temperature point T₁ are respectively searched for in the SOC database, and a first-order linear interpolation is performed to obtain SOC_{V,I1,T1} as follows:

$${SOC}_{V , I 1 , T 1} = \frac{{SOC}_{V 1 , I 1 , T 1} - {SOC}_{V 0 , I 1 , T 1}}{{V}_{1} - {V}_{0}} * ( V - {V}_{0} ) + {SOC}_{V 0 , I 1 , T 1} .$$

Step e3 includes the following steps.
(1) A first-order linear interpolation is performed using the SOC_{V,I0,T0} and SOC_{V,I1,T0} calculated in step e2 to obtain

$${SOC}_{V , I , T 0} = \frac{{SOC}_{V , I 1 , T 0} - {SOC}_{V , I 0 , T 0}}{{I}_{1} - {I}_{0}} * ( I - {I}_{0} ) + {SOC}_{V , I 0 , T 0} .$$

(2) A first-order linear interpolation is performed using the SOC_{V,I0,T1} and SOC_{V,I,T1} calculated in step e2 to obtain

$${SOC}_{V , I , T 1} = \frac{{SOC}_{V , I 1 , T 1} - {SOC}_{V , I 0 , T 1}}{{I}_{1} - {I}_{0}} * ( I - {I}_{0} ) + {SOC}_{V , I 0 , T 1} .$$

In step e4, a first-order linear interpolation is performed using the SOC_{V,I,T0} and SOC_{V,I,T1} calculated in step e3 to obtain

$${SOC}_{V , I , T} = \frac{{SOC}_{V , I , T 1} - {SOC}_{V , I , T 0}}{{T}_{1} - {T}_{0}} * ( T - {T}_{0} ) + {SOC}_{V , I , T 0} .$$

The SOC_{V,I,T} obtained in this manner is the required SOC obtained from the SOC database for a case of the battery parameter (V, I, T).

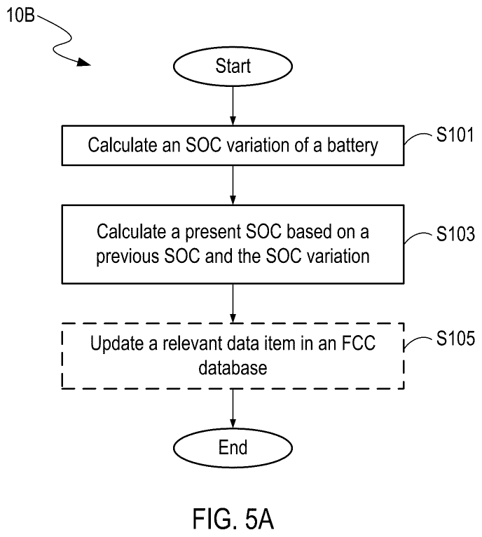

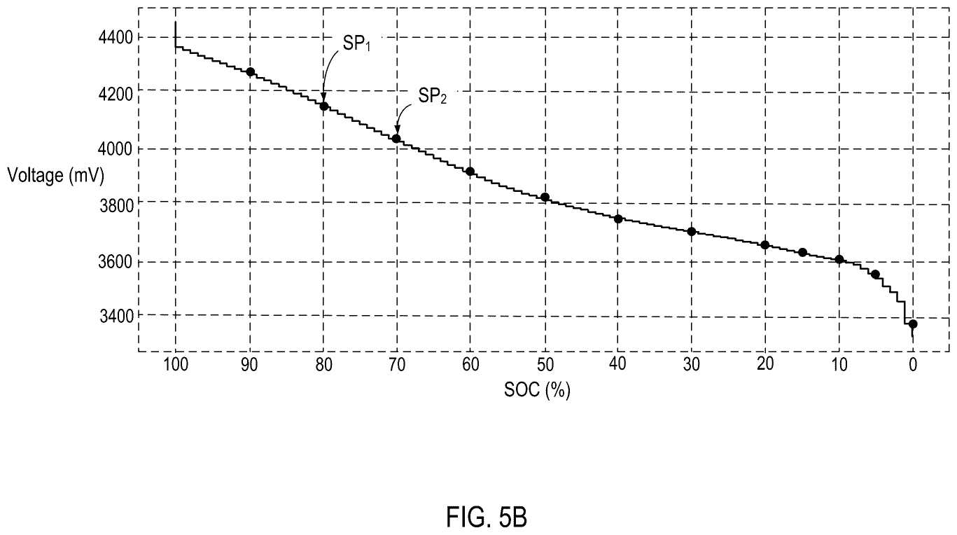

Next, a further embodiment involving an update of the FCC database is described with reference to FIG. 5A to FIG. 7. Those skilled in the art will understand that an update of the FCC database may also be used determine the original/initial values for the data in the database.

As shown in FIG. 5A, in an embodiment, a method 10B for determining a state of charge of a battery further includes a step S105 of updating, when a predetermined update condition is met, a relevant data item in the first FCC database and/or the second FCC database using a calculation error between a first calculated SOC (e.g., the abovementioned SOCₙ calculated based on a corrected FCC) and a second calculated SOC (e.g., calculated based on a regular method, e.g., the Coulomb integration method, that does not involve the corrected FCC). In some embodiments, the abovementioned SOC historical data includes a value of the first calculated SOC, and the abovementioned SOC regular data includes a value of the second calculated SOC.

Here, “the first calculated SOC” may be an SOC at a discharge record point.

Specifically, throughout the entire discharge process, N+1 data record points SP (store_point) may be selected and recorded, to record discharge state data in a present SOC state. Discharge state data record DSG_RD (Discharge Record) stores and updates the discharge state data in a format of (N+1)×M. Here, i represents a serial number of a data record point, with a range of i=0 to N, corresponding to N+1 SOC record synchronization points during the discharge process. M represents a discharge state corresponding to a present record point. In an example, the discharge state includes a present SOC SOC_now, a present temperature T, a present load current I, and a presently accumulative coulomb capacity integral value CC_mah.

The process of recording is shown in FIG. 5B. During the discharge process, when the real-time SOC decreases to a specified SOC (e.g., labeled as data record point SPᵢ such as the SP₁ and SP₂ shown in FIG. 5B), a present discharge state Mi is recorded synchronously; and otherwise, a next calculation is performed continuously without recording. Alternatively, each calculated SOC may be directly treated as a record point.

As an example, a predetermined update condition may include: a maximum difference between SOCs at record points (also referred to as an SOC range or span) in the discharge state data record DSG_RD exceeds a predetermined threshold, and/or a maximum difference between temperatures at record points (also referred to as a temperature range or span) in the discharge state data record DSG_RD exceeds a predetermined threshold. Such a condition indicates that parameters for correcting the FCC is required to be adjusted in a case where the battery state varies significantly during the discharge process.

As an example, calculation errors between the first calculated SOCs (e.g., represented by SOC) and second calculated SOCs (e.g., represented by EST_SOCᵢ) at the data record points SPᵢ (i=0, 1, 2, . . . , N) may be obtained, and a statistical value of the calculation errors, such as but not limited to a median, an average, or an expectation, can be further obtained.

In some embodiments, the first calculated SOCs can be determined based on equations (1) and (2) mentioned above. An example of a method of obtaining the second calculated SOC (e.g., represented by EST_SOCᵢ) corresponding to the data record point SPᵢ in DSG_RD includes using the following equations:

$${CC}_{start} = min ( {CC}_{i} ) ( i = 0 - N ) ;$$

$${CC}_{end} = max ( {CC}_{i} ) ( i = 0 - N ) ;$$

$${SOC}_{end} = min ( {SOC}_{i} ) ( i = 0 - N ) ;$$

$${EST\_SOC}_{i} = \frac{{CC}_{i} - {CC}_{end}}{{CC}_{start} - {CC}_{end}} + {SOC}_{end} ( i = 0 - N ) .$$

Here, CCᵢ represents an accumulative integral value of a coulombmeter (e.g., indicative of the charge quantity stored in the battery) recorded at the record point SPᵢ, CCₛₜₐᵣₜ represents a charge capacity in the initial discharge stage (e.g., when the battery begins discharging from a full charge) obtained based on all recorded data, and CC_{end} represents a discharge termination charge capacity obtained based on all recorded data. SOC_{end} represents a discharge cutoff SOC obtained based on all recorded data. Thus, the second calculated SOC, e.g., EST_SOCᵢ, can be determined based on counting charges that flow through the battery, which can reflect an actual status or a real-time status of the charges stored in the battery. In some embodiments, the second calculated SOC can also be referred to as “actual SOC.”

In an example, such as in the update of the second FCC database, a calculation error, e.g., presented by ΔSOC_errorᵢ, may be determined based on a difference between the first calculated SOC (e.g., SOC) and the second calculated SOC (e.g., EST_SOCᵢ). In this case, SOC errors of each record point SPᵢ in the DSG_RD may be calculated to obtain N+1 calculation errors.

$$Δ {SOC\_error}_{i} = {EST\_SOC}_{i} - {SOC}_{i} . \qquad Equation ( 5 )$$

In another example, such as in the update of the first FCC database, one calculated error may be determined based on statistics (such as but not limited to an average, a median, and an expectation) of differences between multiple first calculated SOCs and multiple corresponding second calculated SOCs. For example, based on the above Equation (5), an average SOC error (“one calculation error”) of all record points SPᵢ in the DSG_RD may be further calculated as:

$$Δ SOC\_avgerror = \frac{{\sum }_{0}^{N} {ΔSOC\_error}_{i}}{N + 1} . \qquad Equation ( 6 )$$

Subsequently, the obtained calculation error may be applied to update data items in a corresponding FCC database.

In an embodiment, in the above-described update, in the first FCC database and/or the second FCC database, a relevant data item to be updated is determined at least based on a battery parameter used during calculation of an SOC (the battery parameter used for calculating the SOC). For example, because the first FCC database is used in an initial correction stage, the battery parameter used during calculation of an SOC here refers to a set of battery parameters corresponding to a SOC₀ in an initial stage. Because the second FCC database is used in real time, the battery parameter used during calculation of an SOC here refers to a set of battery parameters corresponding to a latest SOC (SOCₙ₋₁) obtained through real-time calculation or at a present instant.

In an embodiment, one or more data items whose battery parameters have the highest similarity with the battery parameter corresponding to the battery parameter used during calculation of an SOC may be determined from a corresponding FCC database, as a relevant data item to be updated. The similarity may be determined based on a difference between battery parameters. Optionally, multiple relevant data items may be determined based on multiple battery parameters.

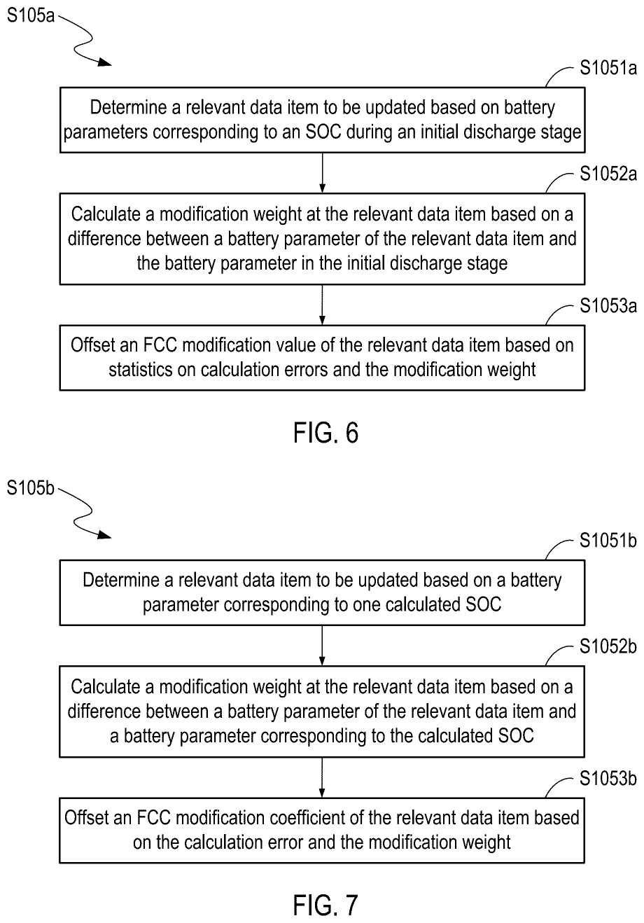

First, an example of updating the first FCC database is described with reference to FIG. 6. Specifically, as shown in FIG. 6, as an example of the update step S105 in FIG. 5A, the update S105a includes step S1051a to step S1053a. In step S1051a, a relevant data item to be updated is determined based on a battery parameter corresponding to an SOC in an initial discharge stage. In step S1052a, a modification weight of the relevant data item is calculated based on a difference between the battery parameter of the relevant data item and the battery parameter corresponding to the SOC in the initial discharge stage. as described below. In step S1053a, a modification value at the relevant data item is calculated based on the aforementioned one calculation error (e.g., ΔSOC_avgerror determined from statistics on differences between multiple first calculated SOCs, e.g., SOCᵢ, and multiple corresponding second calculated SOCs, e.g., EST_SOCᵢ) and the modification weight of the relevant data item, to offset an FCC modification value of the relevant data item.

In step S1051a, one or more data items whose battery parameter have the highest similarity with the battery parameter corresponding to an SOC in the initial discharge stage may be determined from the first FCC database, as a relevant data item to be updated. The above determination may be implemented, for example, by acquiring temperature Tₛₜₐᵣₜ, current Iₛₜₐᵣₜ in a starting stage in the DSG_RD record, and then searching the first FCC database for I, I₂ closest to the Iₛₜₐᵣₜ in a dimension of current I, and T₁, T₂ closest to the Tₛₜₐᵣₜ in a dimension of temperature T, to obtain corresponding 2*2=4 data items through the respective combination of the four parameters (I₁, I₂), (T₁, T₂) in two dimensions.

In step S1052a, a weight Weight_{I} in the dimension of the current I, and a weight Weight_{T} in the dimension of the temperature T, of the relevant data item are calculated based on a difference between the battery parameter of the relevant data item and the battery parameter (Iₛₜₐᵣₜ, Tₛₜₐᵣₜ) in the initial discharge stage:

$${Weight}_{{I}_{1}} = \frac{{I}_{i} - {I}_{1}}{{I}_{2} - {I}_{1}} , {Weight}_{{I}_{2}} = 1 - {Weight}_{{I}_{1}} ;$$

$${Weight}_{{T}_{1}} = \frac{{T}_{i} - {T}_{1}}{{T}_{2} - {T}_{1}} , {Weight}_{{T}_{2}} = 1 - {Weight}_{{T}_{1}} .$$

In step S1053a, based on the above-described one calculation error, e.g., ΔSOC_avgerror, and the above-described modification weight, modification values FCC_offset_Error_{k,m} of four relevant data items determined by four parameters I₁, I₂, T₁, T₂ in the first FCC database are calculated, to offset FCC modification values FCC_offset_{k,m} of the relevant data item.

$$FCC\_offset {\_Error}_{k , m} = {FCC}_{c} * ΔSOC\_avgerror * {Weight}_{{I}_{k}} * {Weight}_{{T}_{m}} ;$$

$$FCC\_offset {\_update}_{k , m} = {FCC\_offset}_{k , m} + FCC\_offset {\_Error}_{k , m} .$$

Here, k=[1,2], m=[1,2], and FCC_c in the above equation may be a predetermined constant for dimensional conversion, for transforming an SOC as a percentage value into a direct correction item of a full charge capacity. For example, FCC_c may be a design capacity FCC_{design} of a battery. Alternatively, FCC_c in the above equation may be the remaining capacity RCA_{dsg} after a discharge task estimated based on the design capacity FCC_{design} of the battery as described above in step b3 (that is, the RCA_{dsg}=FCC_{design}*(SOC_{full}−SOC_{end}), as an initial FCC).

Next, an example of updating the second FCC database is described with reference to FIG. 7. As shown in FIG. 7, as an example of the update step S105 in FIG. 5A, the update S105b includes step S1051b to step S1053b. In step S1051b, a relevant data item to be updated is determined based on a battery parameter corresponding to a particular calculated SOC. In step S1052b, a modification weight of the relevant data item is calculated based on a difference between the battery parameter of the relevant data item and the battery parameter corresponding to that particular calculated SOC. In step S1053b, a modification value of the relevant data item is calculated based on an abovementioned calculation error ΔSOC_errorᵢ and the modification weight of the relevant data item, to offset an FCC modification coefficient of the relevant data item.

In step S1051b, one or more data items whose respective battery parameter(s) has the highest similarity with the battery parameter corresponding to the particular calculated SOC may be determined from the second FCC database, as the relevant data item to be updated. The above determination may be implemented through the following steps.

First, a temperature Tᵢ, current Iᵢ, and state of charge SOCᵢ of a record point SPᵢ in DSG_RD are obtained, where i=0~N.

Then, the second FCC database is searched for: SOC₁, SOC₂ that are closest to SOC; in the dimension of SOC; I₁, I₂ that are closest to Iᵢ in the dimension of the current I; and T₁, T₂ that are closest to Tᵢ in the dimension of temperature T. Therefore, corresponding 2*2*2=8 relevant data items are determined through the respective combination of the six parameters (SOC₁, SOC₂), (I₁, I₂), (T₁, T₂) in three dimensions.

In step S1052b, a weight Weight_{SOC} in the dimension of the state of charge SOC, a weight Weight_{I} in the dimension of the current I, and a weight Weight_{T} in the dimension of the temperature T at the relevant data item, are calculated based on a difference between the battery parameter of the relevant data item and the battery parameter (SOCᵢ, Iᵢ, Tᵢ) corresponding to the SOCᵢ:

$${Weight}_{{SOC}_{1}} = \frac{{SOC}_{i} - {SOC}_{1}}{{SOC}_{2} - {SOC}_{1}} , {Weight}_{{SOC}_{2}} = 1 - {Weight}_{{SOC}_{1}} ;$$

$${Weight}_{{I}_{1}} = \frac{{I}_{i} - {I}_{1}}{{I}_{2} - {I}_{1}} , {Weight}_{{I}_{2}} = 1 - {Weight}_{{I}_{1}} ;$$

$${Weight}_{{T}_{1}} = \frac{{T}_{i} - {T}_{1}}{{T}_{2} - {T}_{1}} , {Weight}_{{T}_{2}} = 1 - {Weight}_{{T}_{1}} .$$

In step S1053b, based on the above-described calculation error ΔSOC_errorᵢ and the above-described modification weight, modification values FCC_ratio_Error_{j,k,m} of eight relevant data items determined by six parameters SOC₁, SOC₂, I₁, I₂, T₁, T₂ in the second FCC database are calculated, to offset FCC modification coefficients FCC_ratio_{j,k,m} of the relevant data item:

$$FCC\_ratio {\_Error}_{j , k , m} = {ΔSOC\_error}_{i} * {Weight}_{{SOC}_{j}} * {Weight}_{{I}_{k}} * {Weight}_{{I}_{m}} ;$$

$$FCC\_ratio {\_update}_{j , k , m} = {FCC\_ratio}_{j , k , m} + FCC\_ratio {\_Error}_{j , k , m} .$$

Here, j=[1,2], k=[1,2], m=[1,2].

Updating the first FCC database and the second FCC database is described above with reference to FIG. 4 to FIG. 7.

Although different examples are described separately, these examples may be combined with each other or performed individually. That is, in the case of using either the first FCC database or the second FCC database individually, the used database is updated based on a set of data records (dataset) obtained. In the case of using both the first FCC database and the second FCC database to obtain a dataset with the method described with reference to FIG. 3B, an identical dataset may be used to update both the first FCC database and the second FCC database.

Alternatively, even when both the first FCC database and the second FCC database are used to obtain a dataset, the present dataset may first be used to update one of the databases. After the updated database is obtained, the method in FIG. 3B is performed again to obtain other data, with which the other database is updated.

Additionally, in some embodiments, a method of obtaining data from the updated FCC database can be the same as or similar to a method of obtaining data from the original FCC database. Therefore, based on the FCC data update described above, a method for constructing an initially-used FCC database may be obtained.

### Second Embodiment

An apparatus for determining a state of charge of a battery is provided according to the present embodiment.

FIG. 8 illustrates a block diagram of functional modules of an apparatus or computing system for determining a state of charge of a battery according to the second embodiment. In an embodiment, the apparatus is implemented in a battery-powered electronic devices such as but not limited to mobile phones and palmtop computers, to determine a SOC of the battery of the device.

As shown in the embodiment of FIG. 8, an apparatus 80 includes processing circuitry 810, memory 830, and a battery 840. In an embodiment, the memory 830 includes an SOC database 832 and an FCC database 834. In an embodiment, the apparatus includes a display window (not shown) for displaying the SOC of the battery 840.

The processing circuitry 810 is configured to: calculate a state of charge SOC variation of the battery 840 based on a variation in charge quantity stored in the battery and a corrected full charge capacity FCC obtained through correction by an FCC modification parameter; and calculate a present SOC based on a previous SOC and the SOC variation of the battery, where the previous SOC is determined at least partially based on the SOC database 832 storing a battery parameter and an SOC in association with each other (e.g., the battery parameter indexes, or is indexed by, the SOC), and where the FCC modification parameter is obtained through the FCC database 834 storing at least a battery parameter and an FCC modification parameter in association with each other (e.g., the battery parameter indexes, or is indexed by, the FCC modification parameter), and the FCC modification parameter stored in the FCC database is determined based on an error between SOC historical data and SOC regular data, where the SOC historical data is obtained through a corrected FCC. Alternatively, the apparatus 80 includes acquisition circuitry 820 configured to obtain parameters required for processing by the processing circuitry 810. In embodiments, the acquisition circuitry 820 includes a sensor for measuring a battery parameter. In some embodiments, as used herein, “FCC modification parameter” can include an abovementioned FCC modification value FCC_offset and/or an abovementioned FCC modification coefficient FCCᵣₐₜᵢₒ₋ₙ.

In the above description of the method for determining a state of charge of a battery, processes and functions implemented by functional modules of the apparatus 80 have been disclosed. In summary, the method steps and processes described with reference to the figures above may be implemented by the processing circuitry 810 in combination with and/or controlling the acquisition circuitry 820. The acquisition circuitry 820 is configured to obtain battery parameters, and the processing circuitry 810 is configured to perform processing, calculations, and control operations. Therefore, in the following, a summary of functions of the processing circuitry will not be provided in cases where some details have been discussed in the preceding text.

The processing circuitry 810 may be implemented as, for example, a chip, processor, microcontroller(s), and the like, and may be implemented by one or more dedicated integrated circuits and/or corresponding software programs. For example, the acquisition circuitry 820 may include at least one sensor and acquire a state parameter of the battery 840 (battery parameter) through the at least one sensor. As described above, the battery parameter may include at least one of battery voltage, battery current, and temperature, but is not limited thereto. For example, optionally, the battery parameter may include (discharge) charge quantity. For example, the acquisition circuitry 820 may include a temperature sensor to measure/determine battery temperature, a current sensing circuit to measure/determine battery current, a voltage sensing circuit to measure/determine battery voltage, and a coulombmeter to measure/determine charge quantity.

Optionally, the SOC database 832 stores SOC values obtained by discharging the battery 840 in states with different battery parameters.

In an example, the processing circuitry 810 is further configured to obtain the variation in charge quantity stored in the battery 840, which is determined through measurement.

In an embodiment, the FCC database 834 may include: a first FCC database storing a first battery parameter in an initial discharge stage and an initial FCC modification value (e.g., as a first FCC modification parameter) in association with each other; and/or a second FCC database storing a second battery parameter and a real-time FCC modification coefficient (e.g., as a second FCC modification parameter) in association with each other.

The first battery parameter may include a battery temperature and a battery current, and/or the second battery parameter may include a battery temperature, a battery current, and an SOC.

In an example, the processing circuitry 810 may be further configured to: query the first FCC database based on a battery parameter in the initial discharge stage to obtain an initial FCC modification value; query the SOC database based on the battery parameter in the initial discharge stage to obtain a full charge SOC and a discharge cutoff SOC, to determine an initial FCC; and correct the initial FCC based on the initial FCC modification value to determine an initial corrected FCC.

In an example, the processing circuitry 810 may be further configured to: query the second FCC database based on a present battery parameter to obtain a real-time FCC modification coefficient; correct a previous FCC based on the real-time FCC modification coefficient to determine a present corrected FCC; and calculate an SOC variation of the battery 840 based on the variation in charge quantity stored in the battery and the corrected FCC.

In an example, the processing circuitry 810 may be further configured to: update, when a predetermined update condition is met, a relevant data item in the first FCC database and/or the 10 second FCC database by using a calculation error between a first calculated SOC (e.g., SOC) and a second calculated SOC (e.g., EST_SOCᵢ).

In an example, the processing circuitry 810 may be further configured to: determine a relevant data item to be updated in the first FCC database and/or the second FCC database at least based on a battery parameter used during calculating an SOC.

Optionally, the processing circuitry 810 may be further configured to: determine multiple relevant data items based on multiple battery parameters.

In an example, the processing circuitry 810 may be further configured to: determine, for the first FCC database, one calculation error (e.g., ΔSOC_avgerror) based on statistics of differences between multiple first calculated SOCs and multiple corresponding second calculated SOCs.

In an example, the processing circuitry 810 may be further configured to: determine, for the second FCC database, an calculation error (e.g., ΔSOC_errorᵢ) based on a difference between a first calculated SOC and a corresponding second calculated SOC.

In an example, the processing circuitry 810 may be further configured to: determine a relevant data item to be updated based on a battery parameter corresponding to a calculated SOC; calculate a modification weight at the relevant data item based on a difference between a battery parameter of the relevant data item and a battery parameter corresponding to the calculated SOC; and calculate a modification value at the relevant data item based on the one calculation error and the modification weight at the relevant data item, to offset an FCC modification coefficient of the relevant data item.

In an example, the processing circuitry 810 may be further configured to: calculate a modification weight at a relevant data item based on the differences of multiple battery parameters.

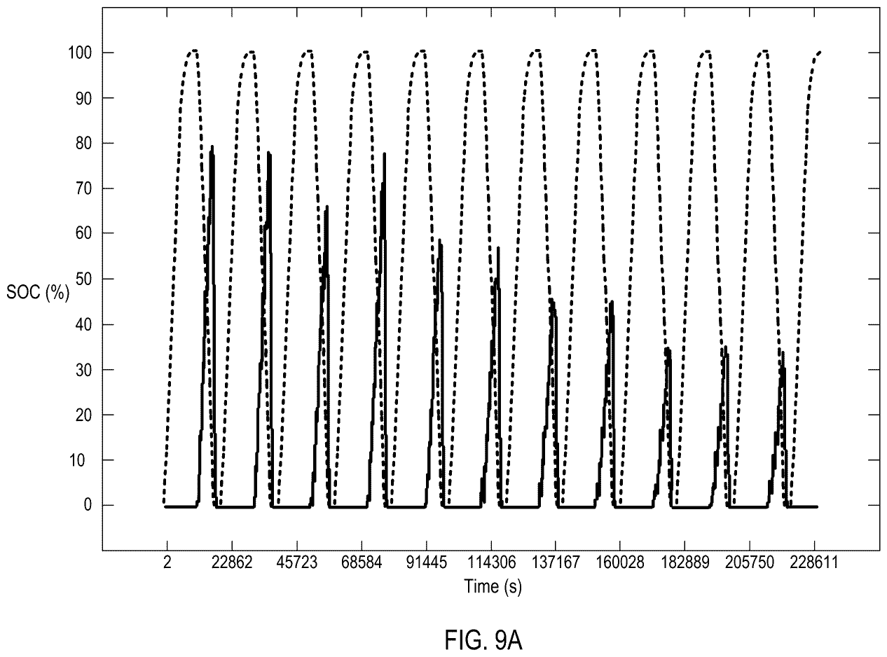

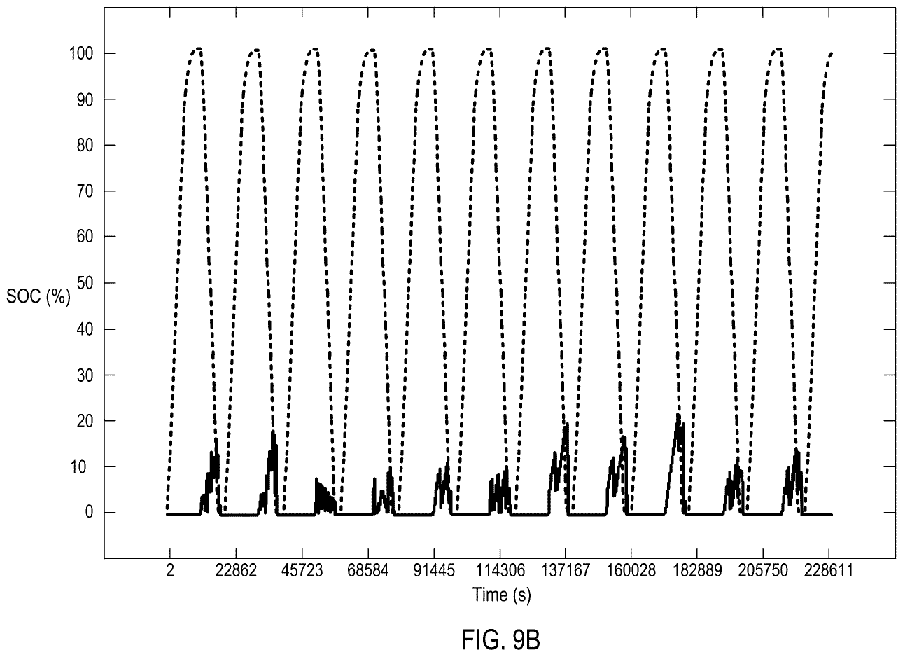

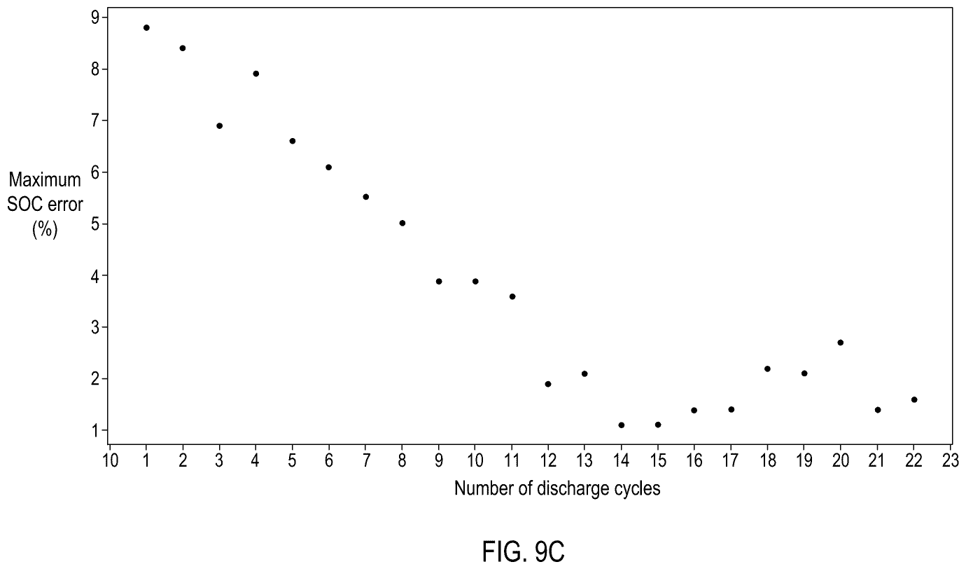

Significant technical effects can be obtained according to the above-described embodiments of the present disclosure. Specifically, FIG. 9A to FIG. 9B show SOC test curves for a set of rechargeable batteries with a model of CA516384Q which are charged and discharged at 25° C. and at a rate of 0.5 C for multiple cycles according to an embodiment of the present disclosure. FIG. 9A shows SOC curves from the 1st discharge to the 11th discharge, where the dashed curve represents a charge/discharge curve of the SOC, and the solid (non-dashed) curve represents an SOC error during the discharge process. In FIG. 9A, the horizontal axis represents time in units of seconds, and the vertical axis represents SOC in units of percentage. FIG. 9B shows SOC curves and errors from the 12th discharge to the 22nd discharge. In FIG. 9B, the horizontal axis represents time in units of seconds, and the vertical axis represents SOC in units of percentage.

During the 1st to 22nd continuous charge-discharge cycles, the SOC error during the discharge process gradually decreases and eventually converges within a stable range after being adjusted through adaptive compensation correction based on SOC discharge parameters according to the methods disclosed herein. Maximum SOC errors for each of the 22 discharge processes are recorded in table 1. Distribution of the maximum SOC errors throughout the discharge processes is shown in FIG. 9C, where the horizontal axis represents the number of discharge cycles, and the vertical axis represents the SOC error in the unit of percentage.

TABLE 1
Maximum SOC Errors through Adaptive Compensation Correction

| | Number of times of | | | | | | | | | | |
|---|---|---|---|---|---|---|---|---|---|---|---|
| | discharge cycles | | | | | | | | | | |
| | 1 | 2 | 3 | 4 | 5 | 6 | 7 | 8 | 9 | 10 | 11 |
| Maximum SOC | 8.87 | 8.48 | 6.92 | 7.93 | 6.60 | 6.18 | 5.51 | 5.04 | 3.89 | 3.96 | 3.68 |
| error (%) | | | | | | | | | | | |
| | Number of times of | | | | | | | | | | |
| | discharge cycles | | | | | | | | | | |
| | 12 | 13 | 14 | 15 | 16 | 17 | 18 | 19 | 20 | 21 | 22 |
| Maximum SOC | 1.90 | 2.11 | 1.09 | 1.19 | 1.46 | 1.39 | 2.22 | 2.15 | 2.77 | 1.39 | 1.61 |
| error (%) | | | | | | | | | | | |

In summary, in the method and apparatus according to the disclosed embodiments, during the calculation of the SOC of the battery, a corrected FCC obtained through correction by an FCC modification parameter in the FCC database storing a battery parameter and an FCC modification parameter in association with each other is used. The FCC modification parameter is determined based on an error between SOC historical data and SOC regular data, where the SOC historical data is obtained through a previous corrected FCC (e.g., a value of an FCC that is corrected previously), and the SOC regular data is obtained through a regular method that does not involve the previous corrected FCC. In this way, the FCC can be appropriately modified by the error between SOC historical data and SOC regular data, thereby improving the accuracy of the SOC. More specifically, in some embodiments, the regular method can include the Coulomb integration method that counts charges flowing through the battery, which can reflect an actual status or a real-time status of the charges stored in the battery. As a result, the FCC can be corrected based the actual status or the real-time status of the battery.

Principles of the present disclosure have been described above in conjunction with specific embodiments. However, it should be noted that for those skilled in the art, all or any of the steps or components of the method and apparatus according to the present disclosure can be implemented in a form of hardware, firmware, software or a combination thereof in any computing device (including a processor, a storage medium and the like) or a network of computing devices. Such implementation can be realized by those skilled after reading the description of the present disclosure, by utilizing general knowledge in circuitry design or general programming skills.

Moreover, a program product storing machine-readable instruction codes is further provided according to the present disclosure. The instruction codes, when read and executed by a machine, implement the method according to the embodiments of the present disclosure.

Accordingly, a storage medium (e.g., the memory 830 of FIG. 8) for storing the program product storing the machine-readable instruction codes is further provided according to the present disclosure. The storage medium includes, but is not limited to, a floppy disk, an optical disk, a magneto-optical disk, a storage card, a memory stick, and the like.

In a case of implementing the present disclosure by software or firmware, a program constituting the software is installed from a storage medium or a network to a computer with a dedicated hardware structure.

In the apparatus, method and system according to the present disclosure, the components or steps may be decomposed and/or recombined. These decompositions and/or re-combinations shall be regarded as equivalent solutions of the disclosure. Furthermore, steps for executing the above processes may be executed in a chronological order as described, but do not necessarily need to be executed in that chronological order. Certain steps may be performed in parallel with or independently of each other.

At last, the terms “include”, “comprise” or any variants thereof are intended to be non-exclusive. Therefore, a process, method, article or apparatus including a series of elements includes not only the elements but also other elements that are not enumerated, or further includes elements inherent to the process, method, article or apparatus. Unless expressively limited, the statement “comprising/including a(n) . . . ” does not exclude existence of other similar elements in the process, method, article or apparatus other than enumerated elements.

Although the embodiments of the present disclosure are described in detail above with reference to the accompanying drawings, the disclosed embodiments are only for illustrating the present invention and do not constitute a limitation of the present invention. For those skilled in the art, various modifications and changes can be made to the disclosed embodiments without departing from the spirit and scope of the present disclosure. Therefore, the scope of the present disclosure is limited by only the appended claims and equivalents thereof.

What is claimed is:

1. A computer-implemented method for determining a state of charge (SOC) of a battery, the method comprising:
calculating an SOC variation of the battery based on a variation in charge quantity stored in the battery and a corrected full charge capacity (FCC), wherein the corrected FCC is determined through correction of a value of an initial FCC using an FCC modification parameter; and
calculating a present SOC based on a previous SOC and the SOC variation,
wherein the previous SOC is determined at least partially based on an SOC database that stores a battery parameter and an SOC that are associated with each other; and
wherein the FCC modification parameter is determined based on an FCC database that stores at least a battery parameter and an FCC modification parameter that are associated with each other, wherein the FCC modification parameter stored in the FCC database is determined based on an error between SOC historical data and SOC regular data, and wherein the SOC historical data is determined using a previous corrected FCC, and the SOC regular data is determined by calculating a charge quantity stored in the battery.

2. The computer-implemented method according to claim 1, wherein the FCC database comprises at least a database of a first FCC database and a second FCC database;
wherein the first FCC database stores a first battery parameter and an initial FCC modification value that are associated with each other;
wherein the second FCC database stores a second battery parameter and a real-time FCC modification coefficient that are associated with each other; and
wherein the FCC modification parameter stored in the FCC database comprises at least one of the initial FCC modification value and the real-time FCC modification coefficient.

3. The computer-implemented method according to claim 2, wherein:
the first battery parameter comprises a battery temperature and a battery current; and
the second battery parameter comprises a battery temperature, a battery current, and an SOC.

4. The computer-implemented method according to claim 2, further comprising an initial correction step of:
querying the first FCC database based on a battery parameter in an initial discharge stage to obtain an initial FCC modification value;
querying the SOC database based on the battery parameter in the initial discharge stage to obtain a full charge SOC and a discharge cutoff SOC that are used to determine an initial FCC; and
correcting the initial FCC based on the initial FCC modification value to determine an initial corrected FCC.

5. The computer-implemented method according to claim 2, further comprising:
querying the second FCC database based on a present battery parameter to obtain a real-time FCC modification coefficient; and
correcting a previous FCC based on the real-time FCC modification coefficient to determine a present corrected FCC.

6. The computer-implemented method according to claim 2, further comprising: updating, when a predetermined update condition is met, a relevant data item in the FCC database using a calculation error between a first calculated SOC and a second calculated SOC, wherein the first calculated SOC is determined based on a corrected FCC, and wherein the second calculated SOC is determined by calculating the charge quantity stored in the battery.

7. The computer-implemented method according to claim 6, wherein in the FCC database, a relevant data item to be updated is determined at least based on a battery parameter used for calculating the SOC of the battery.

8. The computer-implemented method according to claim 7, wherein a plurality of relevant data items are determined based on a plurality of battery parameters.

9. The computer-implemented method according to claim 7, wherein for the first FCC database, the calculation error is determined based on statistics on differences between a plurality of first calculated SOCs and a plurality of corresponding second calculated SOCs.

10. The computer-implemented method according to claim 7, wherein for the second FCC database, the calculation error is determined based on a difference between a single first calculated SOC and a single corresponding second calculated SOC.

11. The computer-implemented method according to claim 10, wherein said updating comprises:
determining the relevant data item to be updated based on a battery parameter corresponding to the single first calculated SOC;
calculating a modification weight for the relevant data item based on a difference between a battery parameter of the relevant data item and a battery parameter corresponding to the single first calculated SOC; and
calculating a modification value for the relevant data item based on the calculation error and the modification weight for the relevant data item, to modify an FCC modification coefficient of the relevant data item.

12. The computer-implemented method according to claim 11, wherein the modification weight for the relevant data item is calculated based on the differences between battery parameters of a plurality of battery parameters.

13. The computer-implemented method according to claim 1, wherein SOC values obtained by discharging the battery in states with different battery parameters are stored in the SOC database.

14. The computer-implemented method according to claim 1, wherein the variation in charge quantity stored in the battery is determined through measurement.

15. A machine-readable program product comprising a machine-readable program, wherein the machine-readable program, when executed by a processor, performs the method for determining a state of charge of a battery according to claim 1.

16. An apparatus for determining a state of charge (SOC) of a battery, the apparatus comprising:
memory; and
processing circuitry coupled to the memory and configured to:
calculate an SOC variation of the battery based on a variation in charge quantity stored in the battery and a corrected full charge capacity (FCC), wherein the corrected FCC is determined through correction of a value of an initial FCC using an FCC modification parameter; and
calculate a present SOC based on a previous SOC and the SOC variation,
wherein the previous SOC is determined at least partially based on an SOC database in the memory that stores a battery parameter and an SOC that are associated with each other; and
wherein the FCC modification parameter is determined based on an FCC database in the memory that stores at least a battery parameter and an FCC modification parameter that are associated with each other, wherein the FCC modification parameter stored in the FCC database is determined based on an error between SOC historical data and SOC regular data, and wherein the SOC historical data is determined using a previous corrected FCC, and the SOC regular data is determined by calculating a charge quantity stored in the battery.

17. The apparatus according to claim 16, wherein the FCC database comprises at least a database of a first FCC database and a second FCC database;
wherein the first FCC database stores a first battery parameter and an initial FCC modification value that are associated with each other;
wherein the second FCC database stores a second battery parameter and a real-time FCC modification coefficient that are associated with each other; and
wherein the FCC modification parameter stored in the FCC database comprises at least one of the initial FCC modification value and the real-time FCC modification coefficient.

18. The apparatus according to claim 17, wherein the processing circuitry is further configured to: update, when a predetermined update condition is met, a relevant data item in the FCC database using a calculation error between a first calculated SOC and a second calculated SOC, wherein the first calculated SOC is determined based on a corrected FCC, and wherein the second calculated SOC is determined by calculating the charge quantity stored in the battery.

19. The apparatus according to claim 18, wherein the processing circuitry is further configured to: determine a relevant data item in the first FCC database to be updated based on a battery parameter used for calculating the SOC of the battery.

20. The apparatus according to claim 16, wherein:
the first battery parameter comprises a battery temperature and a battery current; and
the second battery parameter comprises a battery temperature, a battery current, and an SOC.
